(19) United States
(12) Patent Application Publication
(10) Pub. No.: US 2021/0043474 A1
(43) Pub. Date: Feb. 11, 2021

(54) PLASMA ETCHING APPARATUS

(71) Applicant: DISCO CORPORATION, Tokyo (JP)

(72) Inventors: Masatoshi WAKAHARA, Tokyo (JP); Hideyuki SANDOH, Tokyo (JP)

(21) Appl. No.: 16/983,098

(22) Filed: Aug. 3, 2020

(30) Foreign Application Priority Data
Aug. 9, 2019 (JP) 2019-147054

(51) Int. Cl. H01L 21/67; H01L 21/683; H01L 23/544; H01J 37/32

(52) U.S. Cl. CPC H01L 21/67092; H01L 21/67069; H01L 21/6831; H01L 21/6836; H01L 23/544; H01J 2237/20235; H01J 37/32761; H01L 2221/68336; H01L 2223/5446; H01J 2237/334; H01J 2237/20228; H01J 37/32715

(57) ABSTRACT

A plasma etching apparatus for processing a workpiece of a frame unit including the workpiece formed with division start points or division grooves along a plurality of mutually intersecting streets, and a frame that has an opening and that supports the workpiece on inside of the opening through an expanding tape includes a plasma etching unit that has a chuck table for holding the workpiece on a holding surface through the expanding tape and that supplies a plasmatized gas to the workpiece held by the chuck table, and an expanding unit that expands the expanding tape to divide the workpiece along the division start points or to widen a width of the division grooves.

### BACKGROUND OF THE INVENTION

### Field of the Invention

The present invention relates to a plasma etching apparatus for processing a workpiece.

### Description of the Related Art

In a manufacturing step of device chips, a wafer formed with a device such as an integrated circuit (IC) or a large scale integration (LSI) in each of regions partitioned by a plurality of streets (division lines) arranged in a grid pattern is used. The wafer is divided along the streets, whereby a plurality of chips (device chips) individually having the devices are obtained.

For the division of the wafer, a cutting apparatus that includes a chuck table (holding table) for holding the workpiece, and a cutting unit to which an annular cutting blade for cutting the workpiece is mounted is used. The cutting blade in rotation is made to cut into the workpiece held by the chuck table along the streets, whereby the wafer is cut and divided into a plurality of chips. In addition, in recent years, a technology for dividing a wafer by use of a laser processing apparatus for processing the workpiece by irradiation with a laser beam has been proposed. For example, the wafer is irradiated with a laser beam along the streets, whereby modified regions (modified layers) are formed inside the wafer. The regions in which the modified layers are formed become more brittle than other regions of the wafer. Therefore, when an external force is applied to the wafer formed with the modified layers along the streets, the wafer is ruptured along the streets and is divided into a plurality of chips.

When the wafer is processed by the cutting blade or the laser beam, processing marks such as cracks, strains, and modified layers are formed in the processed regions of the wafer. When the processing marks are left in the chips obtained by division of the wafer, die strength (bending strength) of the chips is lowered. Therefore, it is preferable to remove the processing marks after processing of the wafer. In view of this, the processed wafer may be subjected to plasma etching. The plasma etching is performed by use of a plasma etching apparatus that supplies the workpiece with a plasmatized gas. When the processing marks remaining in the processed regions of the wafer are removed by plasma etching, a lowering in die strength of the chips is thereby restrained.

The plasma etching apparatus includes a pair of flat plate-shaped electrodes disposed to face each other in a chamber (see Japanese Patent Laid-Open No. 2006-73592). When a high-frequency voltage is impressed on the pair of electrodes while an etching gas supplies into the chamber, the etching gas is plasmatized in the chamber. The etching gas in the plasma state acts on the wafer, whereby the wafer is etched, and the processing marks are removed. On the other hand, a plasma etching apparatus that processes a wafer by introducing into a chamber an etching gas plasmatized in the outside of the chamber may be used (see Japanese Patent Laid-Open No. 2018-156973). When this plasma etching apparatus is used, the etching gas easily enters into the narrow regions (the inside of the grooves formed by cutting of the wafer, the inside of cracks extending from modified layers, etc.) inside the wafer, and the processing marks formed in the wafer are efficiently removed.

### SUMMARY OF THE INVENTION

As above-mentioned, the wafer divided into a plurality of chips is processed by the plasma etching apparatus, whereby the processing marks are removed. The wafer from which the processing marks are removed is conveyed from the plasma etching apparatus to other processing apparatus or cleaning apparatus, in the state of being divided into the plurality of chips. However, the vibrations or shocks during conveyance may cause the adjacent chips to make contact with each other, resulting in the formation of damages or cracks in the chips. Particularly, in the case where the wafer formed with a multiplicity of devices in a high density is divided, the distance between the adjacent chips is short (for example, 30 μm or below), and contact between the chips is more liable to occur. When the processing marks remaining in the chips are removed by plasma etching but the chips make contact with each other in the latter conveyance to generate damages or cracks in the chips, die strength of the chips would be lowered. As a result, there arises a problem that the quality and yield of the chips obtained finally are lowered.

The present invention has been made in consideration of such problems. It is therefore an object of the present invention to provide a plasma etching apparatus with which a lowering in die strength of device chips can be restrained.

In accordance with an aspect of the present invention, there is provided a plasma etching apparatus for processing a workpiece of a frame unit including the workpiece formed with division start points or division grooves along a plurality of mutually intersecting streets, and a frame that has an opening and supports the workpiece on inside of the opening through an expanding tape. The plasma etching apparatus includes a plasma etching unit that has a chuck table for holding the workpiece on a holding surface through the expanding tape and that supplies a plasmatized gas to the workpiece held by the chuck table, and an expanding unit that expands the expanding tape to divide the workpiece along the division start points or to widen a width of the division grooves.

Note that preferably, the plasma etching unit includes a chamber that accommodates the chuck table and that has an opening and shutting door through which the frame unit is passed, and the plasma etching apparatus further includes a conveying unit that conveys the frame unit between the chuck table and the expanding unit. In addition, preferably, the expanding unit includes a frame holding section that holds the frame of the frame unit disposed on the holding surface of the chuck table, and a frame holding section moving unit that moves the frame holding section in a direction perpendicular to the holding surface of the chuck table. Besides, preferably, the expanding unit includes a slack removing unit that removes a slack of the expanding tape generated by expansion of the expanding tape.

The plasma etching apparatus according to an aspect of the present invention includes the plasma etching unit that supplied a plasmatized gas to the workpiece, and the expanding unit that expands the expanding tape adhered to the workpiece. When this plasma etching apparatus is used, the processing of the workpiece by plasma etching and the enlargement of the spacings between the chips by expansion of the expanding tape can be performed in the same apparatus. When the spacings between the chips are widened by the expansion of the expanding tape, the chips hardly make contact with each other when the workpiece having been subjected to the plasma etching is conveyed from the plasma etching apparatus to other processing apparatus or cleaning apparatus. As a result, generation of damages or cracks in the chips after the plasma etching is restrained, and a lowering in die strength of the chips is prevented.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1A is a perspective view of a workpiece;

FIG. 1B is a sectional view depicting in an enlarged form a part of the workpiece at which a modified layers are formed;

FIG. 2 is a plan view schematically depicting a plasma etching apparatus;

FIG. 3 is a sectional view depicting a plasma etching unit;

FIG. 4A is a sectional view depicting an expanding unit;

FIG. 4B is a sectional view depicting the expanding unit that expands an expanding tape;

FIG. 5A is a sectional view depicting the expanding unit that removes a slack of the expanding tape;

FIG. 5B is a sectional view depicting the expanding unit after the slack of the expanding tape is removed; and

FIG. 6 is a sectional view depicting the expanding unit provided in a chamber of the plasma etching unit.

### DETAILED DESCRIPTION OF THE PREFERRED EMBODIMENT

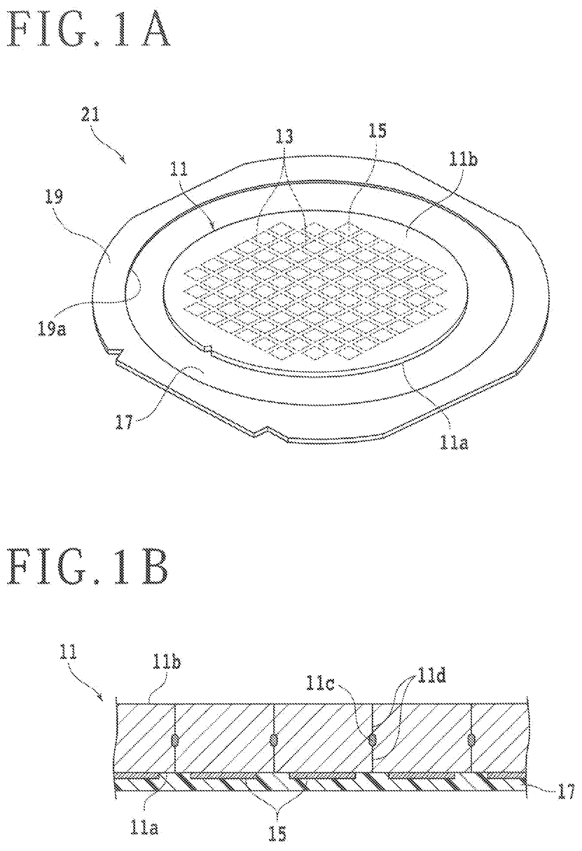

An embodiment of the present invention will be described below referring to the attached drawings. First, a configuration example of a workpiece which can be processed by a plasma etching apparatus according to the present embodiment will be described. FIG. 1A is a perspective view depicting a workpiece 11.

The workpiece 11 is, for example, a silicon wafer formed in a disk-like shape, and has a front surface 11a and a back surface 11b. The workpiece 11 is partitioned into a plurality of regions by a plurality of streets (division lines) 13 arranged in a grid pattern such as to mutually intersect, and a device 15 such as an IC or an LSI is formed on the front surface 11a side of each of the regions. Note that the material, shape, structure, size and the like of the workpiece 11 are not limited. For example, the workpiece 11 may be a wafer of any shape and size which includes a semiconductor other than silicon (GaAs, InP, GaN, SiC, etc.), glass, ceramic, resin, metal or the like. In addition, the kind, number, shape, structure, size, layout and the like of the devices 15 are also not limited.

A circular expanding tape 17 larger in diameter than the workpiece 11 is adhered to the workpiece 11. The expanding tape 17 is a tape (expandable tape) which can be expanded by applying an external force thereto. For example, the expanding tape 17 is adhered to the front surface 11a side of the workpiece 11 such as to cover the plurality of devices 15. Note that the material of the expanding tape 17 is not limited, insofar as the expanding tape 17 is expandable and can be adhered to the workpiece 11. For example, the expanding tape 17 includes a circular base material, and an adhesive layer (glue layer) provided on the base material. The base material includes a resin such as polyolefin, polyvinyl chloride, and polyethylene terephthalate, while the adhesive layer includes an epoxy, acrylic, or rubber-based adhesive or the like. Besides, the adhesive layer may be formed of an ultraviolet (UV)-curing type resin which is cured by irradiation with UV rays.

An outer peripheral part of the expanding tape 17 is adhered to an annular frame 19 including a metal or the like and having a circular opening 19a in its center. Note that the diameter of the opening 19a is larger than the diameter of the workpiece 11, and the workpiece 11 is disposed on the inside of the opening 19a. When the expanding tape 17 is adhered to the workpiece 11 and the frame 19, the workpiece 11 is supported by the frame 19 through the expanding tape 17. Then, a frame unit 21 including the workpiece 11, the expanding tape 17, and the frame 19 is formed.

When the workpiece 11 is divided along the streets 13, a plurality of chips (device chips) individually having the devices 15 are manufactured. The division of the workpiece 11 is carried out, for example, by forming division start points (chances of division) inside the workpiece 11 along the streets 13 and thereafter applying an external force to the workpiece 11.

The division start points are formed by use of, for example, a laser processing apparatus. The laser processing apparatus includes a chuck table (holding table) that holds the workpiece 11 on a holding surface, and a laser applying unit that applies a laser beam toward the workpiece 11 held by the chuck table. The laser applying unit includes a laser oscillator that performs pulsed oscillation of a laser of a predetermined wavelength, and a concentrator that concentrates the laser oscillated from the laser oscillator into a predetermined position.

At the time of forming the division start points in the workpiece 11, a laser beam is applied from the laser applying unit toward the workpiece 11 held by the chuck table. In this instance, the wavelength of the laser beam is set such that the laser beam is transmitted through the workpiece 11 (the laser beam has a transmission property for the workpiece 11). In addition, the laser beam is concentrated in the inside of the workpiece 11 (between the front surface 11a and the back surface 11b). The other application conditions of the laser beam (power, spot diameter, repetition frequency, etc.) are set such that a modified (altered) layer (modified layer or altered layer) is formed inside the workpiece 11 by multiphoton absorption. When the laser beam is applied to the workpiece 11 along the streets 13 in these conditions, modified layers are formed inside the workpiece 11 along the streets 13.

FIG. 1B is a sectional view depicting in an enlarged form a part of the workpiece 11 formed with the modified layers (altered layers) 11c. The modified layers 11c are formed in a grid pattern along the streets 13, inside the workpiece 11. Note that the modified layers 11c may be formed in two or more stages in a thickness direction of the workpiece 11, depending on the thickness of the workpiece 11 or the like. In addition, when the modified layers 11c are formed, cracks lid are generate from the modified layers 11c toward the front surface 11a or the back surface 11b of the workpiece 11. For example, as depicted in FIG. 1B, the cracks 11d are formed such as to reach the front surface 11a and the back surface 11b of the workpiece 11, from the modified layers 11c. The regions in which the modified layers 11c and the cracks 11d are formed become more brittle than other regions of the workpiece 11. Therefore, for example, external forces directed radially outwardly are exerted on the workpiece 11 which has been formed with the modified layers 11c and the cracks 11d, the workpiece 11 is divided with the modified layers 11c and the cracks 11d as start points. In other words, the modified layers 11c and the cracks 11d function as division start points when the workpiece 11 is divided.

For example, when the expanding tape 17 adhered to the workpiece 11 is radially outwardly pulled and expanded after the division start points (the modified layers 11c and the cracks 11d) are formed in the workpiece 11, external forces directed radially outwardly are exerted on the workpiece 11. As a result, the workpiece 11 is ruptured along the streets 13, with the division start points as start points, and is divided into a plurality of chips. Note that the division start points are not limited to the modified layers 11c and the cracks 11d. For example, grooves (cut grooves) formed by cutting the workpiece 11 along the streets 13 by an annular cutting blade, and grooves (laser processed grooves) formed along the streets 13 by ablation processing through irradiation with a laser beam, may also be used as the division start points.

Here, when the workpiece 11 is divided into the plurality of chips with the modified layers 11c and the cracks 11d as the division start points, part of the modified layers 11c may be left on the chips. When the modified layers 11c are left on the chips, die strength (bending strength) of the chips is lowered. For this reason, it is preferable that the modified layers 11c are removed after the cracks 11d extending from the modified layers 11c are formed.

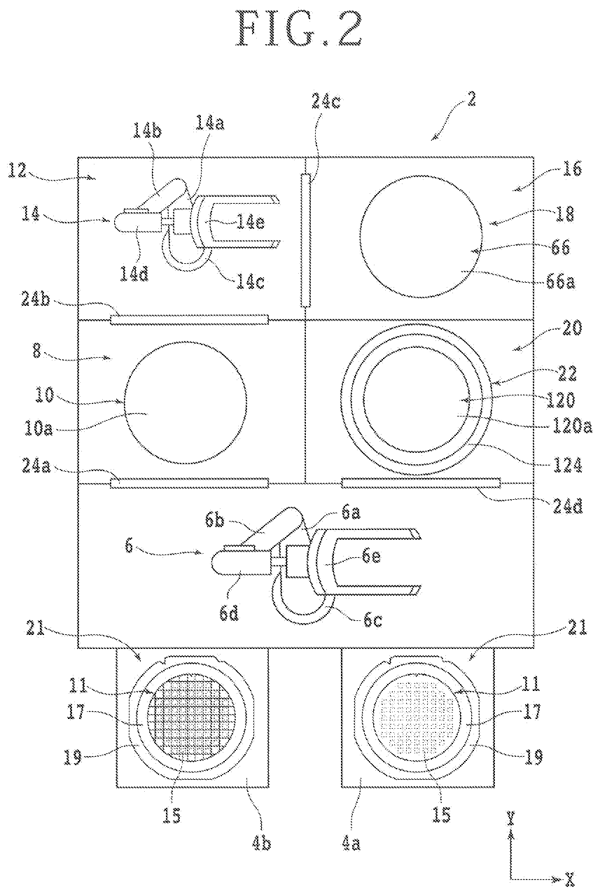

The removal of the modified layers 11c is performed, for example, by subjecting the workpiece 11 to plasma etching by use of a plasma etching apparatus. FIG. 2 is a plan view schematically depicting a plasma etching apparatus 2. The plasma etching apparatus 2 supplies a plasmatized gas to the workpiece 11, thereby etching the workpiece 11.

The plasma etching apparatus 2 includes a cassette mount bases (cassette mount sections) 4a and 4b provided on the front side. Cassettes (not illustrated) in which a plurality of frame units 21 can be accommodated are mounted on the cassette mount bases 4a and 4b. For example, a cassette accommodating a plurality of frame units 21 including the workpieces 11 before processing is mounted on the cassette mount base 4a. In addition, a cassette accommodating a plurality of frame units 21 including the workpieces 11 after processing is mounted on the cassette mount base 4b.

On the rear side of the cassette mount bases 4a and 4b, a conveying unit (conveying means) 6 for conveying the frame unit 21 is provided. The conveying unit 6 conveys out the frame unit 21 (the workpiece 11 before processing) from the cassette mounted on the cassette mount base 4a, and conveys in the frame unit 21 (the workpiece 11 after processing) to the cassette mounted on the cassette mount base 4b.

The conveying unit 6 includes conveying arms 6a and 6b which are slewed in a horizontal plane (XY plane). A moving mechanism (lift mechanism) 6c for moving the conveying arm 6a in the vertical direction (up-down direction) is connected to a base end portion (one end portion) of the conveying arm 6a. In addition, a base end portion (one end portion) of the conveying arm 6b is connected to a tip portion (the other end portion) of the conveying arm 6a. Note that the conveying arms 6a and 6b are connected to a rotating mechanism (not illustrated) such as a motor for rotating the conveying arms 6a and 6b around rotational axes substantially parallel to the vertical direction, and are independently slewed in a horizontal plane. A holding section 6e is connected to a tip portion (the other end portion) of the conveying arm 6b through a connection member 6d which is slewed in a horizontal plane. The holding section 6e holds the workpiece 11 or the frame 19 possessed by the frame unit 21. For example, the holding section 6e holds the upper surface side of the workpiece 11 or the frame 19, without making contact with the workpiece 11 or the frame 19, by utilizing Bernoulli effect. In this case, the conveying unit 6 functions as a non-contact chuck. It is to be noted, however, that the structure of the conveying unit 6 is not limited, so long as the frame unit 21 can be conveyed.

A front chamber (decompression chamber) 8 in which the frame unit 21 is temporarily placed is provided on the rear side of the conveying unit 6. The front chamber 8 includes, for example, a decompression chamber, and a chuck table (holding table) 10 for holding the frame unit 21 is accommodated in the front chamber 8.

An upper surface of the chuck table 10 constitutes a holding surface 10a for holding the workpiece 11 possessed by the frame unit 21. The holding surface 10a is formed substantially in parallel to a horizontal plane, and is connected to a suction source (not illustrated) such as an ejector through a passage (not illustrated) formed inside the chuck table 10. Note that while an example in which the holding surface 10a is formed in a circular shape correspondingly to the shape of the workpiece 11 is illustrated in FIG. 2, the shape and size of the holding surface 10a can be modified, as required, according to the shape and size of the workpiece 11. For example, one frame unit 21 is conveyed out from the cassette mounted on the cassette mount base 4a, by the conveying unit 6. Then, the frame unit 21 is conveyed to the chuck table 10 by the conveying unit 6, and the workpiece 11 is disposed on the holding surface 10a with the expanding tape 17 therebetween. When a negative pressure of the suction source is made to act on the holding surface 10a in this state, the workpiece 11 is held under suction by the chuck table 10. It is to be noted, however, that the structure of the chuck table 10 is not limited, so long as the workpiece 11 can be held.

Note that a frame holding section (not illustrated) for holding the frame 19 supporting the workpiece 11 may be provided in the periphery of the chuck table 10. For example, a plurality of clamps for gripping the frame 19 to fix the frame 19, an annular frame holding member for holding the frame 19 from the lower side, or the like is provided as a frame holding section along an outer peripheral edge of the holding surface 10a. In this case, the workpiece 11 is held by the chuck table 10, and the frame 19 is held by the frame holding section.

An opening and shutting door (gate) 24a through which the frame unit 21 is passed is provided between the conveying unit 6 and the front chamber 8. The frame unit 21 held by the conveying unit 6 is conveyed into the front chamber 8 by passing through the opening and shutting door 24a in an open state.

A conveying chamber (decompression chamber) 12 for accommodating the conveying unit (conveying means) 14 for conveying the frame unit 21 is provided on the rear side of the front chamber 8. In addition, a treatment chamber 16 in which to perform a plasma treatment of the workpiece 11 is provided on a lateral side of the conveying chamber 12. The conveying chamber 12 is connected to the front chamber 8 through an opening and shutting door (gate) 24b, and is connected to the treatment chamber 16 through an opening and shutting door (gate) 24c.

The conveying chamber 12 includes, for example, a decompression chamber, and the conveying unit 14 is provided in the decompression chamber. The conveying unit 14 conveys the frame unit 21 between the front chamber 8 and the treatment chamber 16. For example, the conveying unit 14 includes conveying arms 14a and 14b, a moving mechanism (lift mechanism) 14c, a connection member 14d, and a holding section 14e. Note that the details of the configuration of the conveying unit 14 are similar to those of the conveying unit 6.

An opening and shutting door 24b through which the frame unit 21 is passed is provided between the front chamber 8 and the conveying chamber 12. An opening and shutting door 24c through which the frame unit 21 is passed is provided between the conveying chamber 12 and the treatment chamber 16. In a state in which the opening and shutting doors 24b and 24c are open, the frame unit 21 is conveyed between the front chamber 8 and the treatment chamber 16 by the conveying unit 14. Note that the front chamber 8 is formed with an exhaust port (not illustrated) through which the inside and the outside of the front chamber 8 communicate with each other, and an exhaust mechanism (not illustrated) such as a vacuum pump is connected to the exhaust port. When the exhaust mechanism is operated in a state in which the opening and shutting doors 24a and 24b are closed to hermetically seal the front chamber 8, the inside of the front chamber 8 is decompressed. In addition, the conveying chamber 12 is formed with an exhaust port (not illustrated) through which the inside and the outside of the conveying chamber 12 communicate with each other, and an exhaust mechanism (not illustrated) such as a vacuum pump is connected to the exhaust port. When the exhaust mechanism is operated in a state in which the opening and shutting doors 24b and 24c are closed to hermetically seal the conveying chamber 12, the inside of the conveying chamber 12 is decompressed. Note that the inside of the conveying chamber 12 is normally kept in a decompressed state.

At the time of processing the workpiece 11, first, the opening and shutting door 24a is put into an open state. Then, the conveying unit 6 conveys one frame unit 21 from the cassette mounted on the cassette mount base 4a to the front chamber 8 via the opening and shutting door 24a. Then, the frame unit 21 is held by the chuck table 10 provided in the front chamber 8. Thereafter, the opening and shutting door 24a is put into a closed state, and the inside of the front chamber 8 is decompressed by the exhaust mechanism connected to the front chamber 8.

Next, the opening and shutting doors 24b and 24c are put into an open state. Then, the conveying unit 14 conveys the frame unit 21 from the front chamber 8 into the treatment chamber 16 through the opening and shutting doors 24b and 24c. Note that when the opening and shutting doors 24b and 24c are opened, the front chamber 8 and the conveying chamber 12 are in a decompressed state. As a result, a rise in the pressure inside the treatment chamber 16 when the frame unit 21 is conveyed into the treatment chamber 16 is restrained. A plasma etching unit 18 for subjecting the workpiece 11 to plasma etching is provided in the treatment chamber 16. The workpiece 11 conveyed into the treatment chamber 16 by the conveying unit 14 is processed by the plasma etching unit 18.

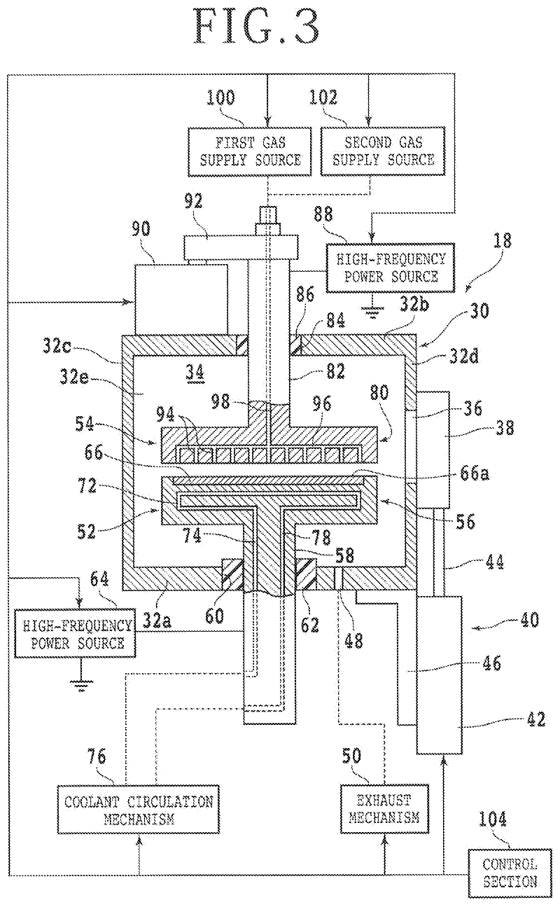

FIG. 3 is a sectional view depicting the plasma etching unit 18. The plasma etching unit 18 includes a chamber 30 formed in a rectangular parallelepiped shape. The chamber 30 includes a bottom wall 32a, an upper wall 32b, a first side wall 32c, a second side wall 32d, a third side wall 32e, and a fourth side wall (not illustrated), and a treatment space 34 in which to perform a plasma treatment is formed inside the chamber 30.

The second side wall 32d is provided with an opening 36 for conveying in and out the workpiece 11 therethrough. An opening and shutting door (gate) 38 for opening and closing the opening 36 is provided on the outside of the opening 36. The opening and shutting door 38 corresponds, for example, to the opening and shutting door 24c illustrated in FIG. 2. The opening and shutting door 38 is moved upward and downward by an opening and shutting mechanism 40. For example, the opening and shutting mechanism 40 includes an air cylinder 42 provided with a piston rod 44. The air cylinder 42 is fixed to the bottom wall 32a of the chamber 30 through a bracket 46, and a tip portion (upper end portion) of the piston rod 44 is connected to a lower portion of the opening and shutting door 38. With the opening and shutting door 38 opened by the opening and shutting mechanism 40, the frame unit 21 can be conveyed into the treatment space 34 in the chamber 30 via the opening 36, or the frame unit 21 can be conveyed out from the treatment space 34.

The bottom wall 32a of the chamber 30 is formed with an exhaust port 48 through which the inside and the outside of the chamber 30 communicate with each other. An exhaust mechanism 50 such as a vacuum pump is connected to the exhaust port 48.

A lower electrode 52 and an upper electrode 54 are disposed in the treatment space 34 of the chamber 30 such as to face each other. The lower electrode 52 is formed of a conductive material, and includes a disk-shaped holding section 56, and a cylindrical support section 58 projecting downward from a central portion of a lower surface of the holding section 56. The support section 58 is inserted in an opening 60 formed in the bottom wall 32a of the chamber 30. In the opening 60, an annular insulating member 62 is disposed between the bottom wall 32a and the support section 58, and the chamber 30 and the lower electrode 52 are insulated from each other. In addition, the lower electrode 52 is connected to a high-frequency power source 64 in the exterior of the chamber 30.

A recess circular in shape in plan view is formed on the upper surface side of the holding section 56, and a chuck table (holding table) 66 on which to mount the workpiece 11 is provided in the recess. An upper surface of the chuck table 66 constitutes a circular holding surface 66a for holding the workpiece 11. The chuck table 66 is an electrostatic chuck table that holds the workpiece 11 by an electrical force (typically, an electrostatic attracting force) or the like.

Specifically, an electrode (not illustrated) is embedded inside the chuck table 66. When a predetermined voltage is impressed on the electrode, an electrical force acts between the chuck table 66 and the workpiece 11, and the workpiece 11 is attracted onto the holding surface 66a of the chuck table 66. Specifically, when a predetermined voltage is impressed on the electrode inside the chuck table 66 in a state in which the workpiece 11 is disposed on the chuck table 66 with the expanding tape 17 (see FIG. 1A and the like) therebetween, the workpiece 11 is attractively held by the chuck table 66 with the expanding tape 17 therebetween. Note that a frame holding section for holding the frame 19 (see FIG. 1A and the like) supporting the workpiece 11 may be provided in the periphery of the chuck table 66.

In addition, a cooling channel 72 is formed inside the holding section 56 of the lower electrode 52. One end of the cooling channel 72 is connected to a coolant circulation mechanism 76 through a coolant introduction passage 74 formed in the support section 58, and the other end of the cooling channel 72 is connected to the coolant circulation mechanism 76 through a coolant discharge passage 78 formed in the support section 58. When the coolant circulation mechanism 76 is operated, the coolant flows sequentially through the coolant introduction passage 74, the cooling channel 72, and the coolant discharge passage 78 to cool the lower electrode 52.

The upper electrode 54 is formed of a conductive material, and includes a disk-shaped gas jetting section 80, and a cylindrical support section 82 projecting upward from a central portion of an upper surface of the gas jetting section 80. The support section 82 is inserted in an opening 84 formed in the upper wall 32b of the chamber 30. In the opening 84, an annular insulating member 86 is disposed between the upper wall 32b and the support section 82, and the chamber 30 and the upper electrode 54 are insulated from each other. The upper electrode 54 is connected to a high-frequency power source 88 in the exterior of the chamber 30. In addition, a support arm 92 connected to a lift mechanism 90 is attached to an upper end portion of the support section 82, and the upper electrode 54 is moved upward and downward by the lift mechanism 90 and the support arm 92.

A plurality of jet ports 94 are provided on the lower surface side of the gas jetting section 80. The jet ports 94 are connected to a first gas supply source 100 and a second gas supply source 102 through a channel 96 formed in the gas jetting section 80 and a channel 98 formed in the support section 82. The first gas supply source 100 and the second gas supply source 102 individually supply different-component gases into the chamber 30.

In addition, the components (the opening and shutting mechanism 40, the exhaust mechanism 50, the high-frequency power source 64, the coolant circulation mechanism 76, the high-frequency power source 88, the lift mechanism 90, the first gas supply source 100, the second gas supply source 102, etc.) of the plasma etching unit 18 are connected to a control section (control unit) 104 including a computer or the like. Operations of the components of the plasma etching unit 18 are controlled by the control section 104.

At the time of processing the workpiece 11 by the plasma etching unit 18, first, the opening and shutting door 38 is lowered by the opening and shutting mechanism 40. Next, the frame unit 21 is conveyed into the treatment space 34 in the chamber 30 through the opening 36 by the conveying unit 14 (see FIG. 2), and the workpiece 11 is mounted on the chuck table 66 such that the back surface 11b side (see FIG. 1A) is exposed to the upper side. Note that at the time of conveying in the frame unit 21, it is preferable to raise the upper electrode 54 by the lift mechanism 90, thereby preliminarily widening the spacing between the lower electrode 52 and the upper electrode 54.

Subsequently, a predetermined voltage is impressed on the electrode (not illustrated) embedded in the chuck table 66, and the workpiece 11 is held by the chuck table 66 with the expanding tape 17 therebetween. In addition, the opening and shutting door 38 is raised by the opening and shutting mechanism 40, to hermetically seal the treatment space 34. Then, the exhaust mechanism 50 is operated to decompress the treatment space 34, to bring the treatment space 34 into a vacuum state (low pressure state). Further, the height position of the upper electrode 54 is controlled by the lift mechanism 90 such that the lower electrode 52 and the upper electrode 54 are brought into a predetermined positional relationship suitable for plasma processing.

Thereafter, while supplying an etching gas at a predetermined flow rate from the first gas supply source 100 or the second gas supply source 102, a high-frequency electric power is supplied to the lower electrode 52 and the upper electrode 54. The etching gas supplied from the first gas supply source 100 or the second gas supply source 102 is supplied to a space between the lower electrode 52 and the upper electrode 54 through the channel 98, the channel 96, and the jet ports 94. For example, in the case where the workpiece 11 is a silicon wafer, in a state in which the inside of the treatment space 34 is kept at a low pressure (for example, 50 to 300 Pa), while supplying a gas such as SF₆ at a predetermined flow rate from the first gas supply source 100 or the second gas supply source 102, a predetermined high-frequency electric power (for example, 1,000 to 3,000 W) is impressed on the lower electrode 52 and the upper electrode 54. As a result, the etching gas is plasmatized between the lower electrode 52 and the upper electrode 54, and the etching gas in the plasma state acts on the back surface lib side of the workpiece 11.

Here, as depicted in FIG. 1B, the workpiece 11 is formed with the cracks 11d extending from the modified layers 11c to reach the back surface 11b of the workpiece 11. The plasmatized gas enters into the cracks 11d, to reach the modified layers 11c. As a result, plasma etching progresses in the inside of the cracks 11d, whereby the modified layers 11c are removed.

After the workpiece 11 is processed by the plasma etching unit 18, the frame unit 21 is conveyed from the plasma etching unit 18 into the front chamber 8 by the conveying unit 14 (see FIG. 2), and is held by the chuck table 10 inside the front chamber 8. The pressure inside the front chamber 8 is controlled to a pressure on the order of the pressure in the region in which the conveying unit 6 is provided. For example, the front chamber 8 is opened to the atmosphere, and a gas (air) is supplied to the inside of the front chamber 8. As a result, the pressure inside the front chamber 8 is raised to the atmospheric pressure, and becomes equal to the pressure in the region in which the conveying unit 6 is provided.

In addition, as illustrated in FIG. 2, a treatment chamber 20 in which to expand the expanding tape 17 adhered to the workpiece 11 is provided on the rear side of the conveying unit 6 and on a lateral side of the front chamber 8. An expanding unit 22 for expanding the expanding tape 17 is accommodated in the treatment chamber 20. Besides, an opening and shutting door (gate) 24d through which the frame unit 21 is passed is provided between the conveying unit 6 and the treatment chamber 20. After the plasma etching of the workpiece 11 is conducted, the frame unit 21 is temporarily placed on the chuck table 10 in the front chamber 8. Then, the pressure inside the front chamber 8 is controlled to a pressure on the order of, for example, the atmospheric pressure, after which the frame unit 21 is conveyed into the treatment chamber 20. Specifically, in a state in which the opening and shutting doors 24a and 24d are in an open state, the conveying unit 6 conveys the frame unit 21 from the front chamber 8 to the expanding unit 22 via the opening and shutting doors 24a and 24d. Then, the expanding tape 17 adhered to the workpiece 11 is expanded by the expanding unit 22.

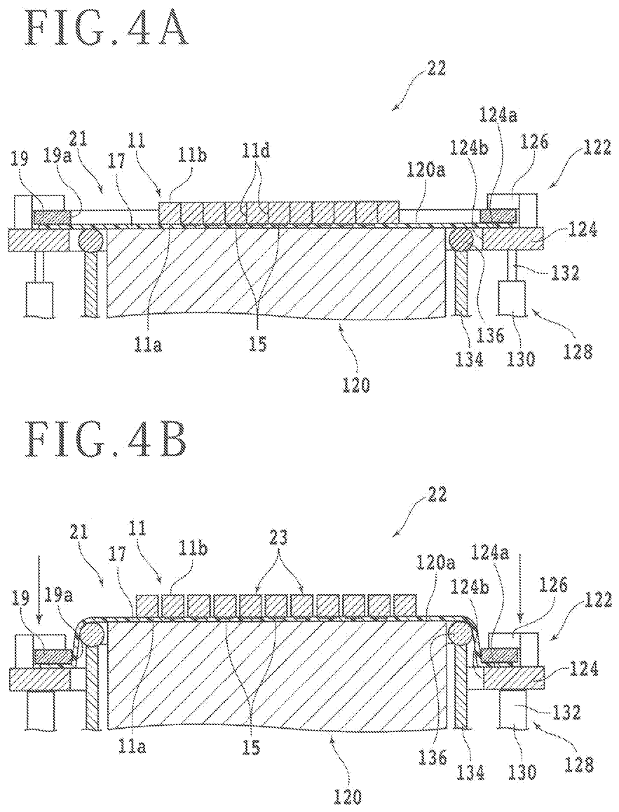

FIG. 4A is a sectional view depicting the expanding unit 22. The expanding unit 22 includes a chuck table (holding table) 120 for holding the workpiece 11, and a frame holding section 122 for holding the frame 19. An upper surface of the chuck table 120 constitutes a holding surface 120a for holding the workpiece 11 thereon. The holding surface 120a is connected to a suction source (not illustrated) such as an ejector via a channel (not illustrated) formed inside the chuck table 120. When a negative pressure of the suction source is made to act on the holding surface 120a, in a state in which the workpiece 11 is disposed on the holding surface 120a with the expanding tape 17 therebetween, the workpiece 11 is held under suction by the chuck table 120 with the expanding tape 17 therebetween. Note that the holding surface 120a of the chuck table 120 is formed in a circular shape correspondingly to the shape of the workpiece 11. It is to be noted, however, that the shape and size of the holding surface 120a may be modified, as required, according to the shape and size of the workpiece 11.

The frame holding section 122 includes an annular frame holding member 124 for holding the frame 19. An upper surface of the frame holding member 124 constitutes an annular holding surface 124a for holding the frame 19. In addition, the frame holding member 124 is formed in its central portion with a circular opening 124b penetrating the frame holding member 124 in the vertical direction. Note that the inside diameter of the frame holding member 124 (the diameter of the opening 124b) is set to be less than the diameter (outside diameter) of the frame 19. Besides, a plurality of clamps 126 for fixing the frame 19 is fixed to the frame holding member 124. The frame 19 disposed on the holding surface 124a of the frame holding member 124 is pressed against the holding surface 124a side by the clamps 126. As a result, the frame 19 is fixed in the state of being interposed between the frame holding member 124 and the clamps 126.

A plurality of moving mechanisms 128 for moving the frame holding section 122 (the frame holding member 124 and the clamps 126) in a direction perpendicular to the holding surface 120a of the chuck table 120 (in the vertical direction) is provided on the lower side of the frame holding member 124. For example, the moving mechanisms 128 each include an air cylinder 130 provided with a piston rod 132. An upper end portion of the piston rod 132 is connected to a lower surface side of the frame holding member 124. With the air cylinders 130 driven to lift the piston rods 132 upward or downward, the position (height) of the frame holding section 122 in the vertical direction is controlled.

In addition, a tape support member 134 that is formed in a hollow cylindrical shape and that supports the expanding tape 17 is provided on outside of the chuck table 120 and on inside of the frame holding member 124. The tape support member 134 is provided such as to surround the chuck table 120, and a plurality of rollers 136 is mounted to an upper end side of the tape support member 134 at substantially regular intervals along the circumferential direction of the tape support member 134. Note that the tape support member 134 is preferably disposed such that the height position of upper ends of the rollers 136 are positioned slightly above the holding surface 120a of the chuck table 120.

When the frame unit 21 is conveyed to the expanding unit 22 by the conveying unit 6 (see FIG. 2), the workpiece 11 is held by the chuck table 120 with the expanding tape 17 therebetween, and the frame 19 is held by the frame holding member 124. In addition, that region of the expanding tape 17 which is located between the workpiece 11 and the frame 19 (the region not overlapping with the workpiece 11 and the frame 19) makes contact with upper end portions of rollers 136. Then, the clamps 126 are operated, and the frame 19 is fixed in the state of being interposed between the frame holding member 124 and the clamps 126. Note that in this instance, the frame holding member 124 is disposed at such a position (initial position) that the holding surface 124a and the holding surface 120a of the chuck table 120 are at substantially the same height.

Next, the expanding tape 17 is expanded by the expanding unit 22. FIG. 4B is a sectional view depicting the expanding unit 22 that expands the expanding tape 17. In a state in which the suction holding of the workpiece 11 (expanding tape 17) by the chuck table 120 is released and the frame 19 is gripped by the frame holding member 124 and the clamps 126, the air cylinders 130 are driven, to lower the frame holding member 124 together with the clamps 126. As a result, the expanding tape 17 is pulled toward radially outer sides in the state of being supported by the rollers 136, and is thereby expanded. When the expanding tape 17 is expanded, external forces directed toward radially outer sides are radially exerted on the workpiece 11 to which the expanding tape 17 is adhered. As a result, the workpiece 11 is ruptured along the division start points (cracks 11d), and is divided into a plurality of chips 23 provided individually with the devices 15 (see FIG. 1A). In addition, when the expanding tape 17 is expanded, the gaps between the chips 23 are widened, whereby a spacing is formed between the adjacent chips 23. Therefore, when the workpiece 11 is later conveyed from the plasma etching apparatus 2, the chips 23 hardly make contact with each other. Consequently, generation of damages or cracks in the chips 23 can be prevented, and a lowering in the die strength of the chips 23 is restrained.

Thereafter, in a state in which a negative pressure of the suction source is made to act on the holding surface 120a and the workpiece 11 is held under suction by the chuck table 120 with the expanding tape 17 therebetween, the air cylinders 130 are driven, to raise the frame holding section 122 to the initial position. As a result, application of the external forces to the expanding tape 17 is released. When the frame holding section 122 is raised while sucking the expanding tape 17 by the chuck table 120, the layout of the chips 23 is maintained even after the application of the external forces to the expanding tape 17 is released.

Note that when the application of the external forces to the expanding tape 17 is released, slackening is liable to occur in the expanding tape 17, particularly, in that region of the expanding tape 17 which is between the workpiece 11 and the frame 19. In view of this, after the frame holding member 124 is returned into the initial position, it is preferable to remove the slack of the expanding tape 17. For example, by heating that region of the expanding tape 17 in which a slack is generated, the slack of the expanding tape 17 can be removed.

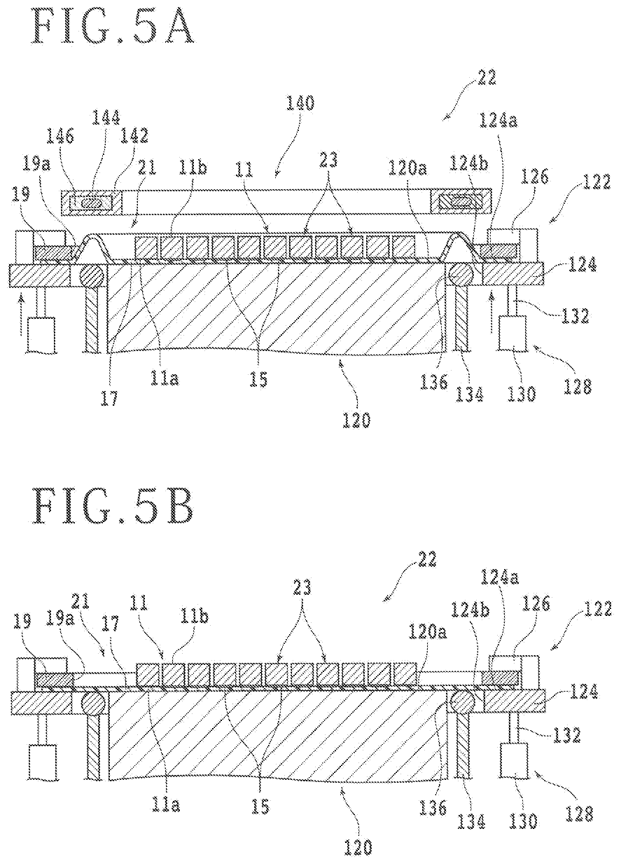

FIG. 5A is a sectional view depicting the expanding unit 22 that removes the slack of the expanding tape 17. For example, the expanding unit 22 includes a slack removing unit (heating unit) 140 for removing the slack of the expanding tape 17. The slack removing unit 140 includes an infrared (IR) heater or the like, and removes the slack by heating the expanding tape 17.

The slack removing unit 140 includes an annular frame 142. The frame 142 includes, for example, a hollow ring formed of a metal such as stainless steel, and an annular heating member 144 formed of nichrome wire or the like is provided inside the frame 142 along the circumferential direction of the frame 142. The heating member 144 is connected to a power source (not illustrated) for supplying the heating member 144 with electric power, and the heating member 144 generates heat when electric power is supplied to the heating member 144. In addition, the heating member 144 is covered with an insulating member 146 formed of magnesium oxide or the like. Note that the diameter of the slack removing unit 140 is set such that the slack removing unit 140 overlaps with the region between the workpiece 11 and the frame 19, that is, that region of the expanding tape 17 in which a slack is liable to be generated. After the expanding tape 17 is expanded, the slack removing unit 140 is disposed on the upper side of the frame unit 21, and the expanding tape 17 is heated by irradiation with IR rays. When the expanding tape 17 is heated by the slack removing unit 140, the slackened region of the expanding tape 17 shrinks, whereby the slack is removed. FIG. 5B is a sectional view depicting the expanding unit 22 after the slack of the expanding tape 17 is removed.

After the expanding tape 17 is expanded, the frame unit 21 is conveyed out from the expanding unit 22 by the conveying unit 6 (see FIG. 2), and is accommodated into the cassette mounted on the cassette mount base 4b. When a predetermined number of frame units 21 (the workpieces 11 after processing) are accommodated in the cassette, the frame units 21 are conveyed together with the cassette to other processing apparatus or cleaning apparatus.

Note that a case where the workpiece 11 is processed by the plasma etching unit 18 and thereafter the expanding tape 17 is expanded by the expanding unit 22 has been described above. It is to be noted, however, that the expansion of the expanding tape 17 may be performed and thereafter the workpiece 11 may be subjected to plasma etching. Specifically, first, one frame unit 21 (the workpiece 11 before processing) accommodated in the cassette mounted on the cassette mount base 4a is conveyed into the treatment chamber 20 by the conveying unit 6, and the expanding tape 17 is expanded by the expanding unit 22. As a result, the workpiece 11 is divided into a plurality of chips 23 (see FIG. 4B), and the spacings between the chips 23 are widened. Thereafter, the frame unit 21 is conveyed into the treatment chamber 16 by use of the conveying unit 6 and the conveying unit 14, and the workpiece 11 is subjected to plasma etching by the plasma etching unit 18. When the workpiece 11 is subjected to the plasma etching after the expanding tape 17 is expanded, the plasmatized etching gas is supplied to the workpiece 11 in a state in which the spacings between the chips 23 are widened. Therefore, it is easy for the etching gas to enter into the spacings between the chips 23, and it is easy to remove the modified layers 11c formed in the workpiece 11.

As described above, the plasma etching apparatus 2 according to the present embodiment includes the plasma etching unit 18 that supplies the plasmatized gas to the workpiece 11, and the expanding unit 22 that expands the expanding tape 17 adhered to the workpiece 11. When the plasma etching apparatus 2 is used, processing of the workpiece 11 by plasma etching and the enlargement of the spacings between the chips 23 by expansion of the expanding tape 17 can be performed in the same apparatus. When the spacings between the chips 23 are widened by expansion of the expanding tape 17, chips 23 hardly make contact with each other when the workpiece 11 having been subjected to the plasma etching is conveyed from the plasma etching apparatus 2 to other processing apparatus, cleaning apparatus or the like. As a result, generation of damages or cracks in the chips 23 after the plasma etching is restrained, and a lowering in die strength of the chips 23 is prevented.

Note that a configuration example of the plasma etching apparatus 2 in which the plasma etching unit 18 and the expanding unit 22 are provided in different treatment chambers (the treatment chambers 16 and 20) and the conveying units (the conveying units 6 and 14) for conveying the frame unit 21 between the chuck table 66 (see FIG. 3) of the plasma etching unit 18 and the expanding unit 22 are provided, has been described in FIG. 2. It is to be noted, however, that the expanding unit may be provided in the treatment chamber 16 that accommodates the plasma etching unit 18. For example, the expanding unit 18 may be provided in the chamber 30 (see FIG. 3) possessed by the plasma etching unit 18.

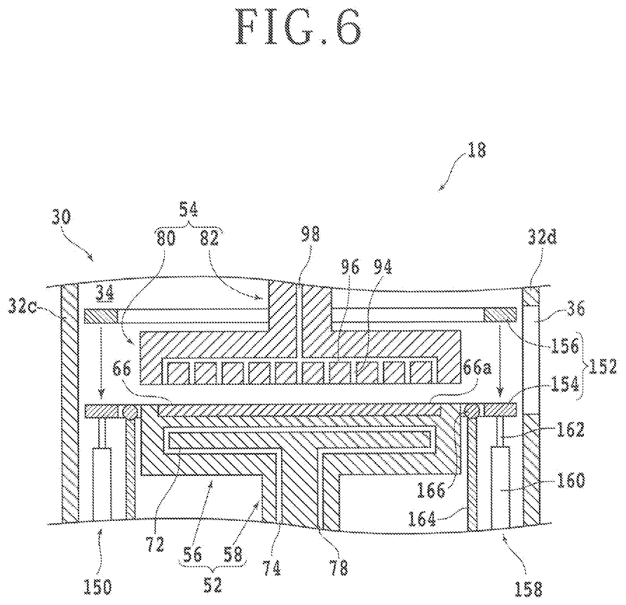

FIG. 6 is a sectional view depicting an expanding unit 150 provided in the chamber 30 of the plasma etching unit 18. The expanding unit 150 that expands the expanding tape 17 (see FIG. 1A and the like) adhered to the workpiece 11 is provided in the treatment space 34 in the chamber 30. The expanding unit 150 includes a frame holding section 152 that holds the frame 19 (see FIG. 1A and the like) possessed by the frame unit 21. The frame holding section 152 includes an annular first frame holding member 154 and an annular second frame holding member 156 for holding the frame 19. The first frame holding member 154 and the second frame holding member 156 are formed substantially in the same diameter correspondingly to the shape of the frame 19, and are disposed such as to overlap with each other.

The first frame holding member 154 is provided such as to surround the holding surface 66a of the chuck table 66. In addition, an upper surface of the first frame holding member 154 constitutes an annular holding surface for holding the frame 19 from the lower side. This holding surface is disposed at substantially the same height as the holding surface 66a of the chuck table 66. Besides, the second frame holding member 156 is provided on the first frame holding member 154, and is disposed, for example, such as to surround the upper electrode 54.

The frame holding section 152 is connected to a frame holding section moving unit that moves the frame holding section 152 along a direction (vertical direction) perpendicular to the holding surface 66a of the chuck table 66. Specifically, a plurality of moving mechanisms 158 for moving the first frame holding member 154 in a direction perpendicular to the holding surface 66a of the chuck table 66 is provided on the lower side of the first frame holding member 154. For example, the moving mechanism 158 includes an air cylinder 160 provided with a piston rod 162. An upper end portion of the piston rod 162 is connected to a lower surface side of the first frame holding member 154. With the air cylinders 160 driven to lift the piston rods 162 upward or downward, the position (height) of the first frame holding member 154 in the vertical direction is controlled. Note that a specific operation of the moving mechanisms 158 is similar to that of the moving mechanisms 128 depicted in FIG. 4A and the like.

In addition, the second frame holding member 156 is connected to a moving mechanism (not illustrated) for moving the second frame holding member 156 along a direction perpendicular to the holding surface 66a of the chuck table 66. When the second frame holding member 156 is moved downward by this moving mechanism, the first frame holding member 154 and the second frame holding member 156 are brought closer to each other. The plurality of moving mechanisms 158 for controlling the movement of the first frame holding member 154 and the moving mechanism for controlling the movement of the second frame holding member 156 constitute the frame holding section moving unit.

Besides, a tape support member 164 that is formed in a hollow tubular shape and that supports the expanding tape 17 is provided on outside of the chuck table 66 and on inside of the frame holding section 152. The tape support member 164 is provided such as to surround the chuck table 66, and a plurality of rollers 166 is mounted to the upper end side of the tape support member 164 at substantially regular intervals along the circumferential direction of the tape support member 164. Note that the tape support member 164 is preferably disposed such that the height position of upper ends of the rollers 166 is positioned slightly above the holding surface 66a of the chuck table 66.

The frame unit 21 (see FIG. 1A and the like) is disposed such that the workpiece 11 is held by the holding surface 66a of the chuck table 66 with the expanding tape 17 therebetween, and that the frame 19 is held by the first frame holding member 154. When the second frame holding member 156 is lowered by the moving mechanism (not illustrated), the frame 19 is interposed and held between the first frame holding member 154 and the second frame holding member 156. Thereafter, in a state in which the workpiece 11 (the expanding tape 17) is not attracted by the chuck table 66 and the frame 19 is held by the frame holding section 152, the frame holding section 152 is lowered by the frame holding section moving unit. As a result, the expanding tape 17 supported by the rollers 166 is pulled toward radially outer sides and expanded.

When the expanding unit 150 is thus provided in the chamber 30, it is ensured that after the workpiece 11 is subjected to plasma etching, the expanding tape 17 can be expanded to widen the spacings between the chips 23, without conveying the workpiece 11. As a result, the chips 23 hardly make contact with each other even when the frame unit 21 after the plasma etching is conveyed by the conveying unit 6 and the conveying unit 14. Note that the expansion of the expanding tape 17 by the expanding unit 150 may be performed immediately before plasma etching.

In addition, in place of the second frame holding member 156, clamps (see clamps 126 in FIG. 4A) fixed to the first frame holding member 154 may be used. In this case, the frame 19 is interposed and fixed between the first frame holding member 154 and the clamps. Then, the clamps are moved in the vertical direction together with the first frame holding member 154 by the plurality of moving mechanisms 158 (the frame holding section moving unit).

Besides, a slack removing unit 140 depicted in FIG. 5A may further be provided in the chamber 30. In this case, after the expanding tape 17 is expanded, the slack generated in the expanding tape 17 can be removed in the chamber 30.

In addition, while a case where the workpiece 11 (see FIG. 1B) formed with the modified layers 11c and the cracks 11d which function as division start points is processed has been described in the present embodiment, the workpiece 11 to be subjected to plasma treatment by the plasma etching unit 18 is not limited to this. For example, the workpiece 11 may be formed with division grooves for dividing the workpiece 11 along the streets 13. For example, the workpiece 11 may be cut along the streets 13 by an annular cutting blade, and divided into a plurality of chips 23. In addition, the workpiece 11 may be cut along the streets 13 through ablation processing by irradiation with a laser beam, and divided into a plurality of chips 23. In this case, division grooves (kerfs) extending from the front surface 11a to reach the back surface 11b of the workpiece 11 are formed in the workpiece 11 in a grid pattern along the streets 13.

Here, processing marks such as strains and cracks generated by cutting or ablation processing may be left on those surfaces of the workpiece 11 which are exposed in the inside of the division grooves (side surfaces of the chips 23). The processing marks cause a lowering in the die strength of the chips 23. In view of this, the workpiece 11 formed with the division grooves is subjected to plasma etching by the plasma etching unit 18. As a result, the processing marks remaining in the division grooves are removed, and a lowering in the die strength of the chips 23 is restrained.

Then, after the plasma etching, the expanding tape 17 adhered to the workpiece 11 is expanded by the expanding unit 22 (see FIG. 4A and the like) or the expanding unit 150 (see FIG. 6), whereby the width of the division grooves (the spacings between the chips 23) is widened. As a result, the chips 23 hardly make contact with each other, and formation of damages or cracks in the chips 23 after the plasma etching can be prevented. Note that the expansion of the expanding tape 17 may be carried out before the plasma etching.

In addition, the plasma etching unit 18 in which the gas plasmatized in the chamber 30 is supplied to the workpiece 11 has been described in the present embodiment (see FIG. 3). It is to be noted, however, that the plasma etching unit 18 may supply a gas plasmatized in the outside of the chamber 30 into the chamber 30.

The other structures, methods and the like according to the above embodiment may be modified, as required, so long as the modifications do not depart from the scope of the object of the present invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A plasma etching apparatus for processing a workpiece of a frame unit including the workpiece formed with division start points or division grooves along a plurality of mutually intersecting streets, and a frame that has an opening and supports the workpiece on inside of the opening through an expanding tape, the plasma etching apparatus comprising:
a plasma etching unit that has a chuck table for holding the workpiece on a holding surface through the expanding tape and that supplies a plasmatized gas to the workpiece held by the chuck table; and
an expanding unit that expands the expanding tape to divide the workpiece along the division start points or to widen a width of the division grooves.

2. The plasma etching apparatus according to claim 1,
wherein the plasma etching unit includes a chamber that accommodates the chuck table and that has an opening and shutting door through which the frame unit is passed, and
the plasma etching apparatus further includes a conveying unit that conveys the frame unit between the chuck table and the expanding unit.

3. The plasma etching apparatus according to claim 1,
wherein the expanding unit includes a frame holding section that holds the frame of the frame unit disposed on the holding surface of the chuck table, and a frame holding section moving unit that moves the frame holding section in a direction perpendicular to the holding surface of the chuck table.

4. The plasma etching apparatus according to claim 1,
wherein the expanding unit includes a slack removing unit that removes a slack of the expanding tape generated by expansion of the expanding tape.
